(19) United States
(12) Patent Application Publication
(10) Pub. No.: US 2026/0090116 A1
(43) Pub. Date: Mar. 26, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Kwangwoong Ahn, Suwon-si (KR); Wansun Kim, Suwon-si (KR); Sunwoo Han, Suwon-si (KR); Yunseok Choi, Suwon-si (KR)

(21) Appl. No.: 19/238,800

(22) Filed: Jun. 16, 2025

(30) Foreign Application Priority Data
Sep. 26, 2024 (KR) 10-2024-0130599

(51) Int. Cl. H10F 39/00; H01L 23/00

(52) U.S. Cl. CPC H10F 39/804; H10F 39/811; H10F 39/8063; H10W 72/963; H10W 72/967; H10W 90/754

(57) ABSTRACT

A semiconductor package including a package substrate, a plurality of upper substrate pads, an image sensor chip on the package substrate, where the image sensor chip includes a sensing region and a pad region at least partially surrounding the sensing region, a plurality of chip pads and a plurality of dummy pads in the pad region, a plurality of bonding wires each electrically connecting respective ones of the plurality of upper substrate pads of the package substrate to respective ones of the plurality of chip pads, a reinforcement wire structure including a plurality of reinforcement wires each connecting at least two dummy pads of the plurality of dummy pads, a dam structure on the plurality of dummy pads and the reinforcement wire structure, a glass on the dam structure and the image sensor chip, and a molding member on the image sensor chip and the plurality of bonding wires.

### CROSS-REFERENCE TO RELATED APPLICATION

This application claims priority benefit of under 35 U.S.C. § 119 to Korean Patent Application No. 10-2024-0130599, filed on Sep. 26, 2024, in the Korean Intellectual Property Office, the disclosure of which is herein incorporated by reference in its entirety.

### TECHNICAL FIELD

The inventive concept relates to a semiconductor package and a method of manufacturing the semiconductor package and more particularly, to a semiconductor package including an image sensor chip and a method of manufacturing the same.

### BACKGROUND

A semiconductor package including an image sensor chip may include a transparent substrate which protects the image sensor chip that converts optical information into an electrical signal. The transparent substrate may be fixed on the image sensor chip by a dam structure. In this case, the dam structure may be deformed by external impact or heat. When the dam structure is deformed, stress may be applied to a contact surface between the image sensor chip and the dam structure, causing cracks to occur in the thin film. Accordingly, there is a need for a semiconductor package capable of minimizing deformation of the dam structure.

### SUMMARY

Example embodiments provide a semiconductor package capable of minimizing deformation of a dam structure that supports glass on an image sensor chip.

Example embodiments provide a method of manufacturing the semiconductor package.

However, the inventive concept is not limited to those mentioned above. Other inventive concepts may be clearly understood by those skilled in the art from the following descriptions.

According to example embodiments, there is provided a semiconductor package including a package substrate, a plurality of upper substrate pads on an upper surface of the package substrate, an image sensor chip on the package substrate, where the image sensor chip includes a sensing region and a pad region at least partially surrounding the sensing region, a plurality of chip pads in the pad region and a plurality of dummy pads in the pad region, a plurality of bonding wires each electrically connecting respective ones of the plurality of upper substrate pads of the package substrate to respective ones of the plurality of chip pads, a reinforcement wire structure including a plurality of reinforcement wires each connecting to at least two dummy pads of the plurality of dummy pads, a dam structure on the plurality of dummy pads and on the reinforcement wire structure that is on the pad region of the image sensor chip, a glass on the dam structure and overlapping the image sensor chip, and a molding member on the image sensor chip and on the plurality of bonding wires.

According to example embodiments, there is provided a semiconductor package including a package substrate, an image sensor chip on the package substrate including a sensing region, a pad region at least partially surrounding the sensing region, a plurality of lenses in the sensing region and a plurality of chip pads in the pad region, a plurality of dummy pads including a plurality of first dummy pads and a plurality of second dummy pads in the pad region of the image sensor chip, a reinforcement wire structure including a plurality of reinforcement wires each including a first end portion connected to a first dummy pad of the plurality of first dummy pads and a second end portion opposite to the first end portion that is connected to a second dummy pad of the plurality of second dummy pads, a plurality of bonding wires each electrically connecting respective ones of a plurality of upper substrate pads to respective ones of the plurality of chip pads, a dam structure on the plurality of dummy pads and on the reinforcement wire structure that is on the pad region of the image sensor chip, a glass on the dam structure and overlapping the image sensor chip, and a molding member on the image sensor chip and on the plurality of bonding wires.

According to example embodiments, there is provided a semiconductor package including a package substrate including a plurality of upper substrate pads on an upper surface of the package substrate and a plurality of lower substrate pads on a lower surface opposite to the upper surface, an image sensor chip on the upper surface of the package substrate, the image sensor chip including a sensing region, a pad region at least partially surrounding the sensing region, a plurality of lenses in the sensing region and a plurality of chip pads in the pad region, a plurality of dummy pads including a plurality of first dummy pads and a plurality of second dummy pads in the pad region of the image sensor chip, a plurality of bonding wires electrically connecting respective ones of the plurality of upper substrate pads of the package substrate to respective ones of the plurality of chip pads, a reinforcement wire structure including a plurality of reinforcement wires where ones of the plurality of reinforcement wires include a first end portion connected to a respective first dummy pad of the plurality of first dummy pads and a second end portion opposite to the first end portion and connected to a respective second dummy pad of the plurality of second dummy pads, a dam structure on the plurality of chip pads and on the plurality of dummy pads and on the plurality of bonding wires and on the reinforcement wire structure that is on the pad region of the image sensor chip, a glass on the dam structure and on the image sensor chip, a molding member on the image sensor chip and on the plurality of bonding wires, and a plurality of external connection members on the plurality of lower substrate pads, respectively.

According to example embodiments, in a method of manufacturing a semiconductor package, a package substrate comprising a plurality of upper substrate pads is formed. An image sensor chip is mounted on the package substrate, the image sensor chip comprises a sensing region, a pad region at least partially surrounding the sensing region a plurality of chip pads in the pad region and a plurality of dummy pads in the pad region. A reinforcement wire structure including a plurality of reinforcement wires each connecting to at least two dummy pads of the plurality of dummy pads is formed. A plurality of bonding wires electrically connecting respective ones of the plurality of chip pads of the image sensor chip to respective ones of the plurality of upper substrate pads is formed. A dam structure on the plurality of dummy pads and on the reinforcement wire structure that is on the pad region of the image sensor chip is formed. A glass is formed on the image sensor chip and on the dam structure. A molding member formed on the image sensor chip and on the plurality of bonding wires.

In example embodiments, the plurality of dummy pads includes a plurality of first dummy pads and a plurality of second dummy pads in an alternating arrangement extending along a portion of the pad region. Forming the reinforcement wire structure comprises: forming the plurality of reinforcement wires, a reinforcement wire of the plurality of reinforcement wires includes a first end portion and a second end portion; bonding the first end portion of the reinforcement wire to a first dummy pad of the plurality of first dummy pads; and bonding the second end portion of the reinforcement wire opposite to the first end portion, to a second dummy pad of the plurality of second dummy pads.

In example embodiments, the plurality of dummy pads includes a plurality of first dummy pads, a plurality of second dummy pads and a plurality of third dummy pads that are spaced apart in a repetitive sequence and forming the reinforcement wire structure comprises forming the plurality of reinforcement wires includes forming a plurality of first reinforcement wires and a plurality of second reinforcement wires, a reinforcement wire of the plurality of reinforcement wires includes a first end portion and a second end portion; bonding the first end portion of a first reinforcement wire to a first dummy pad of the plurality of first dummy pads; bonding the second end portion of the first reinforcement wire opposite to the first end portion, to a second dummy pad of the plurality of second dummy pads; bonding the first end portion of a second reinforcement wire to the second dummy pad; and bonding the second end portion of the second reinforcement wire opposite to the first end portion, to a third dummy pad of the plurality of third dummy pads.

In example embodiments, the plurality of dummy pads includes a plurality of first dummy pads, a plurality of second dummy pads, a plurality of third dummy pads, and a plurality of fourth dummy pads spaced apart in a repetitive sequence, and forming the reinforcement wire structure comprises forming the plurality of reinforcement wires, a reinforcement wire of the plurality of reinforcement wires includes a first end portion and a second end portion; bonding the first end portion of the reinforcement wire to a first dummy pad of the plurality of first dummy pads; and bonding the second end portion of the reinforcement wire opposite to the first end portion to a fourth dummy pad of the plurality of fourth dummy pads.

In example embodiments, the dam structure comprises a rectangular annular shape.

In example embodiments, the dam structure is offset from a perimeter of a backside surface of the image sensor chip.

In example embodiments, mounting the image sensor chip on the package substrate comprises mounting a front surface of the image sensor chip facing the package substrate, and the plurality of chip pads and the plurality of dummy pads are on a backside surface of the image sensor chip opposite to the front surface.

### BRIEF DESCRIPTION OF THE DRAWINGS

Example embodiments will be more clearly understood from the following detailed description taken in conjunction with the accompanying drawings. FIGS. 1, 2, 3, 4, 5, 6, 7, 8, 9, 10, 11, 12, 13, 14, 15, 16, 17 and 18 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ of FIG. 1.

FIG. 3 is a plan view illustrating the semiconductor package in FIG. 1.

FIG. 4 is an enlarged plan view illustrating portion ‘B’ of FIG. 3.

FIG. 5 is a perspective view illustrating portion ‘B’ of FIG. 3.

FIGS. 6, 7, 8, 9, 10, 11 and 12 are views illustrating a method of manufacturing a semiconductor package in accordance with example embodiments.

FIGS. 13, 14 and 15 are views illustrating a semiconductor package in accordance with example embodiments.

FIGS. 16, 17 and 18 are views illustrating a semiconductor package in accordance with example embodiments.

### DETAILED DESCRIPTION OF EXAMPLE EMBODIMENTS

Hereinafter, example embodiments will be explained in detail with reference to the accompanying drawings. The same reference numerals are used for the same components in the drawings, and redundant descriptions thereof are omitted.

The term “first,” “second,” or the like used herein may modify various elements regardless of the order and/or priority thereof and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween. The term “in contact with” may be used herein to specify an element or layer that is directly on another element or layer without the presence of at least one additional element or layer therebetween. The term “surrounding,” “covering” or the like used herein may not require completely on or surrounding or covering the described elements or layers, but may, for example, refer to partially on or surrounding or covering the described elements or layers, for example, with voids or other spaces throughout.

A horizontal direction may include a first direction D1 and a second direction D2 that is intersects perpendicular (i.e., orthogonal) to the first direction D1. A vertical direction D3 (not shown) may be orthogonal to the first direction D1 and the second direction D2.

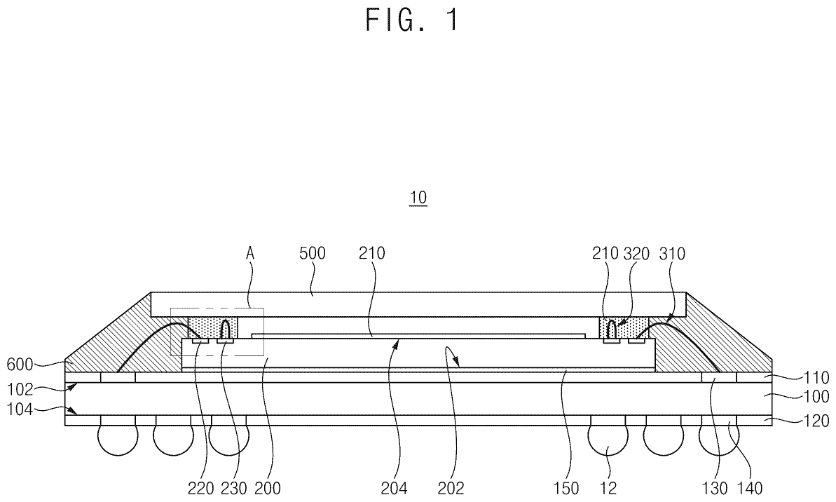

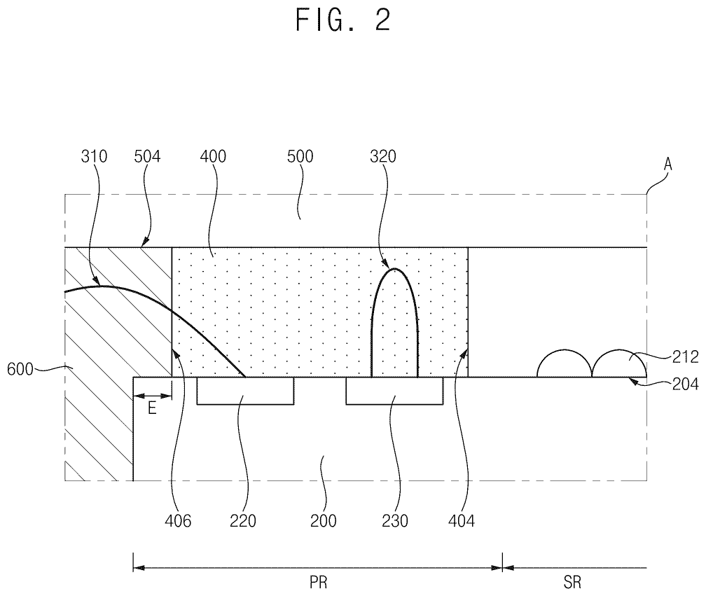

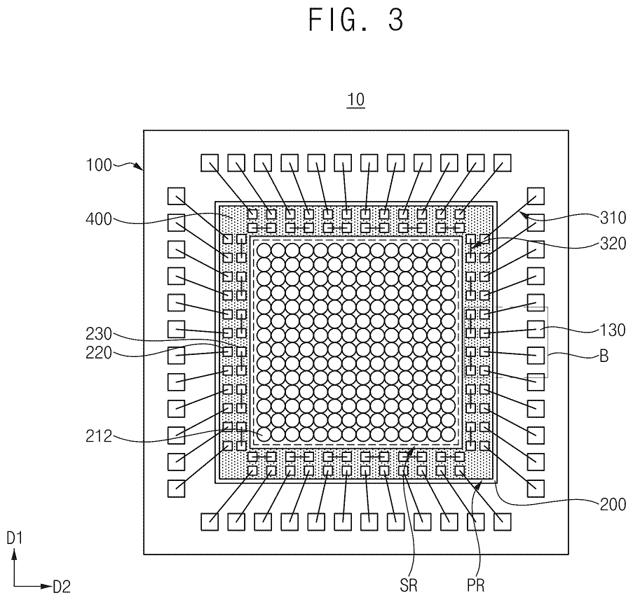

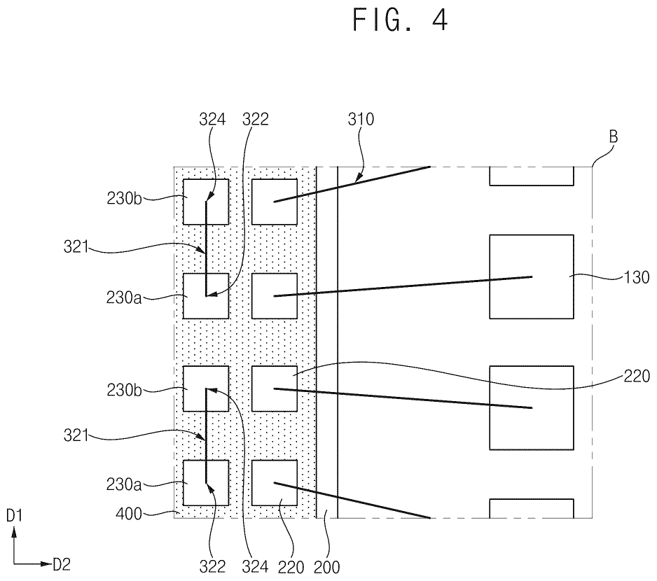

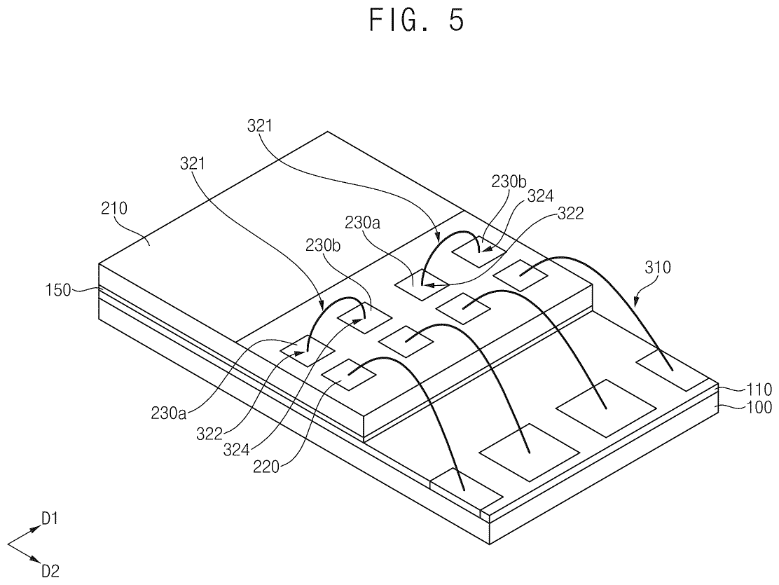

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating the semiconductor package in FIG. 1. FIG. 4 is an enlarged plan view illustrating portion ‘B’ in FIG. 3. FIG. 5 is a perspective view illustrating portion ‘B’ in FIG. 3.

Referring to FIGS. 1, 2, 3, and 4, the semiconductor package 10 may include a package substrate 100, an image sensor chip 200 disposed on the package substrate 100, bonding wires 310 electrically connecting the image sensor chip 200 and the package substrate 100, a reinforcement wire structure 320, a dam structure 400 disposed on the image sensor chip 200, a glass 500 disposed on the image sensor chip 200, and a molding member 600. Additionally, the semiconductor package 10 may further include an external connection member 12 disposed on a lower surface of the package substrate 100.

In example embodiments, the semiconductor package 10 may be an image sensor package including the image sensor chip 200 configured to convert an optical signal into an electrical signal.

In example embodiments, the package substrate 100 may be a multi-layered circuit board package substrate having an upper surface 102 and a lower surface 104 facing each other. For example, the package substrate 100 may be a printed circuit board (PCB) including wirings respectively provided in a plurality of layers and vias for connecting the wirings. The external connection member 12 may be disposed on the lower surface 104 of the package substrate 100.

The package substrate 100 may include an upper insulation layer 110 disposed on the upper surface 102 and a lower insulation layer 120 disposed on the lower surface 104. Additionally, the package substrate 100 may include upper substrate pads 130 and lower substrate pads 140.

The upper insulation layer 110 may be disposed on the upper surface 102 of the package substrate 100 to expose the upper substrate pads 130. The upper substrate pads 130 may be disposed on a peripheral region of the package substrate 100. The upper insulation layer 110 may cover or overlap the entire upper surface 102 of the package substrate 100 except for the upper substrate pads 130. In other words, portions of the upper insulation layer 110 may be adjacent to the upper substrate pads 130 on the package substrate 100. For example, the upper insulation layer 110 may include a solder resist. The upper insulation layer 110 may partially surround the upper substrate pads 130.

The lower insulation layer 120 may be disposed on the lower surface 104 of the package substrate 100 to expose the lower substrate pads 140 as external connection pads for providing electrical signals. The lower substrate pads 140 may be exposed by the lower insulation layer 120. The lower insulation layer 120 may include a solder resist. As will be described later, the external connection member 12 may be disposed on the lower substrate pad 140 of the package substrate 100 for electrical connection with an external device. For example, the external connection member 12 may be a solder ball. The semiconductor package 10 may be mounted on a module substrate (not shown) via the solder balls to constitute an image sensor module.

In example embodiments, the image sensor chip 200 may be mounted on the upper surface 102 of the package substrate 100. For example, the image sensor chip 200 may be attached on the upper surface 102 of the package substrate 100 by an adhesive layer 150. The image sensor chip 200 may have a front surface 202 and a backside surface 204 facing (i.e., opposite) the front surface 202. The image sensor chip 200 may be disposed on the package substrate 100 such that the front surface 202 faces the upper surface 102 of the package substrate 100.

The image sensor chip 200 may have a sensing region SR and a pad region PR at least partially surrounding the sensing region SR on the backside surface 204. The image sensor chip 200 may include a lens layer 210 in the sensing region SR. The image sensor chip 200 may include chip pads 220 and dummy pads 230 in the pad region PR.

The lens layer 210 may include a plurality of lenses 212. The plurality of lenses 212 may include hemispherical microlenses arranged in an array form (i.e., configuration or pattern) on the sensing region SR. The hemispherical microlens may focus an incident light on the image sensor chip 200.

The chip pads 220 may be arranged on the pad region PR to surround the dummy pads 230. For example, the dummy pads 230 and the chip pads 220 may be arranged in two rows to surround the sensing region SR. The chip pads 220 may be arranged in an outer portion of the pad region PR compared to the dummy pads 230. The chip pads 220 may be exposed from the backside surface 204 of the image sensor chip 200. Top surfaces of the chip pads 220 may be located on a same plane as the backside surface 204 of the image sensor chip 200. The chip pads 220 may be portions to which the bonding wires 310 are connected, respectively, as described below.

In example embodiments, the bonding wires 310 may electrically connect the package substrate 100 and the image sensor chip 200. For example, the bonding wire 310 may extend from the chip pad 220 on the backside surface 204 of the image sensor chip 200 to the upper substrate pad 130 on or adjacent to the upper insulation layer 110 of the package substrate 100 to electrically connect the chip pad 220 to the upper substrate pad 130. That is, a first end of the bonding wire may be connected to the upper substrate pad 130, and a second end opposite to the first end may be connected to the chip pad 220. The bonding wire 310 may include gold (Au), copper (Cu), silver (Ag), or aluminum (Al), etc. The bonding wire 310 may not be electrically connected to the dummy pads 230.

As illustrated in FIGS. 3 to 5, the reinforcement wire structure 320 may be disposed on the dummy pads 230.

The reinforcement wire structure 320 may include a reinforcement wire 321 that extends from at least one dummy pad 230. The reinforcement wire 321 may have a first end portion 322 and a second end portion 324 opposite to the first end portion 322. For example, the first end portion 322 and the second end portion 324 of the reinforcement wire 321 may be bonded to a first dummy pad 230a and a second dummy pad 230b, respectively.

As illustrated in FIGS. 4 and 5, the dummy pads 230 are disposed side by side along a first direction D1 in which one side of the image sensor chip 200 extends, and may include the first dummy pads 230a and the second dummy pads 230b arranged adjacent to each other. The first dummy pads 230a and the second dummy pads 230b may be arranged alternately in the first direction D1.

The first end portion 322 of the reinforcement wire may be bonded to the first dummy pad 230a, and the second end portion 324 of the reinforcement wire may be bonded to the second dummy pad 230b. That is, the reinforcement wire 321 may connect (e.g. electrically connect) the first dummy pad 230a to the second dummy pad 230b. In this case, the first dummy pad 230a and the second dummy pad 230b may include pads connected to a same ground. Therefore, even when the first dummy pad 230a and the second dummy pad 230b are electrically connected by the reinforcement wire 321, an electrical short may be prevented.

A plurality of reinforcement wires 321 may be disposed on the first dummy pads 230a and the second dummy pads 230b that are alternately arranged, and each of the plurality of reinforcement wires 321 may extend in the first direction D1. Each of the plurality of reinforcement wires 321 may not be electrically connected to each other. Accordingly, an electrical short may be prevented.

The reinforcement wire 321 may include copper (Cu), aluminum (Al), tungsten, nickel (Ni), molybdenum (Mo), gold (Au), silver (Ag), chromium (Cr), tin (Sn), or titanium (Ti), etc.

In example embodiments, the dam structure 400 may be disposed on the backside surface 204 of the image sensor chip 200. The dam structure 400 may be disposed on the pad region PR of the image sensor chip 200. The dam structure 400 may extend along a circumference (i.e., perimeter) of the backside surface 204 of the image sensor chip 200. For example, the dam structure 400 may have a quadrangular ring shape or an annular ring shape along the circumference of the image sensor chip 200. For example, the dam structure 400 may be offset from a perimeter of a backside of the image sensor chip 200. The dam structure 400 may cover or overlap the dummy pads 230 and the reinforcement wire structure 320 disposed on the dummy pads 230. Additionally, the dam structure 400 may cover or overlap the chip pads 220 and portions of the bonding wires 310 connected to and extending from the chip pads 220.

The dam structure 400 may attach the glass 500 to the image sensor chip 200 and support the glass 500. Additionally, the dam structure 400 may protect the image sensor chip 200 from external moisture or pollutants. The dam structure 400 may include an insulating material.

In example embodiments, the glass 500 may be disposed on the backside surface 204 of the image sensor chip 200. For example, the glass 500 may be disposed on the dam structure 400 such that the glass is supported by the dam structure 400 disposed on the image sensor chip 200. That is, the glass 500 may be spaced apart from the backside surface 204 of the image sensor chip 200 by a distance corresponding to a height of the dam structure 400. The glass 500 may allow an optical signal to reach the lens layer 210 on the image sensor chip 200. The glass 500 may include a material, such as transparent glass, or transparent resin, etc., but is not limited thereto.

In example embodiments, the molding member 600 may be disposed on the package substrate 100 to cover or overlap the image sensor chip 200 and the bonding wires 310. The molding member 600 may be disposed to cover or overlap a side surface of the glass 500. The molding member 600 may be disposed to be in contact with a portion of a lower surface 504 of the glass 500, an outer surface 406 of the dam structure 400, and a portion of the backside surface 204 of the image sensor chip 200. The molding member 600 may cover or overlap a portion of the bonding wire 310 not covered or overlapped by the dam structure 400. The molding member 600 may prevent the lens layer 210 of the image sensor chip 200 and the dam structure 400 from being contaminated by external pollutants. In addition, the molding member 600 may protect the semiconductor package 10 including the image sensor chip 200 from external impact.

As mentioned above, the semiconductor package 10 may include the package substrate 100, the image sensor chip 200 disposed on the package substrate 100 and having the chip pads 220 and the dummy pads 230, the bonding wires 310 electrically connecting the chip pads 220 of the image sensor chip 200 to the upper substrate pads 130 of the package substrate 100, the reinforcement wire structure 320 disposed on the at least one of the dummy pads 230, the dam structure 400 disposed on the image sensor chip 200, the glass 500 supported by the dam structure 400, and the molding member 600 disposed on the image sensor chip 200.

Additionally, the reinforcement wire structure 320 may include the plurality of reinforcement wires 321, and each of the reinforcement wires 321 may have the first end portion 322 and the second end portion 324 opposite to the first end portion 322 that are bonded to different two dummy pads 230. The dam structure 400 may be disposed to cover or overlap the reinforcement wire structure 320.

Accordingly, by taking advantage of the fact that the dummy pads that are used for an EDS inspection process do not perform any special function in a completed semiconductor package and include metal materials, the wire structure may be disposed on the dummy pads. Since the wire structure may be disposed inside the dam structure to support the dam structure, deformation due to external impact or thermal stress may be prevented from occurring in the dam structure during a manufacturing process or after the manufacturing process of the semiconductor package is completed. Since the dam structure has a relatively higher rigidity compared with a related art, there is an advantage of providing a highly reliable semiconductor package.

Hereinafter, a method of manufacturing the package substrate of FIG. 1 will be described.

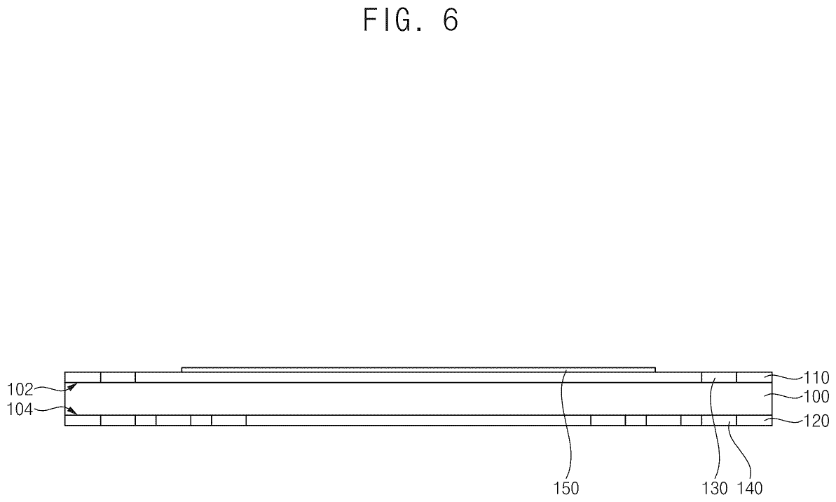

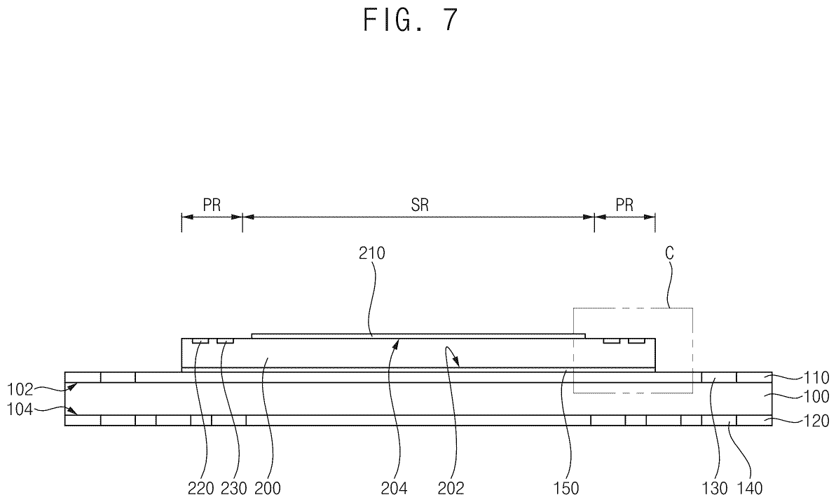

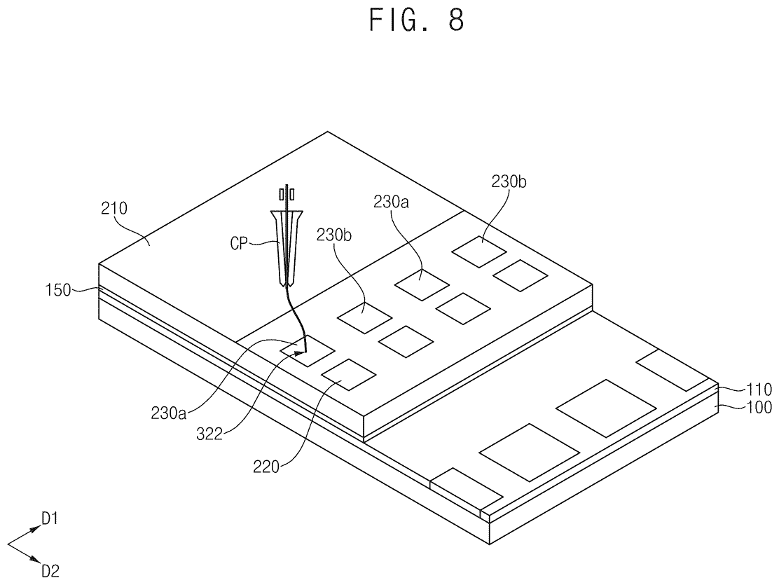

FIGS. 6, 7, 8, 9, 10, 11, and 12 are views illustrating a method of manufacturing a semiconductor package in accordance with example embodiments. FIG. 8 is a perspective view illustrating portion ‘C’ in FIG. 7.

Referring to FIG. 6, first, an adhesive layer 150 may be formed on a package substrate 100.

In example embodiments, the package substrate 100 may be a multi-layered circuit board having an upper surface 102 and a lower surface 104 facing each other. For example, the package substrate 100 may be a printed circuit board (PCB) including wirings respectively provided in a plurality of layers and vias for connecting the wirings. An external connection member 12 may be disposed on a lower surface 104 of the package substrate 100.

The package substrate 100 may include an upper insulation layer 110 disposed on the upper surface 102 and a lower insulation layer 120 disposed on the lower surface 104. Additionally, the package substrate 100 may include upper substrate pads 130 and lower substrate pads 140.

The adhesive layer 150 may be formed on the upper surface 102 of the package substrate 100. The adhesive layer 150 may include, for example, a liquid epoxy, an adhesive tape, or a conductive medium, but example embodiments are not limited thereto.

Referring to FIG. 7, an image sensor chip 200 may be attached onto the adhesive layer 150.

In example embodiments, the image sensor chip 200 may have a front surface 202 and a backside surface 204 facing the front surface 202. The image sensor chip 200 may have a lens layer 210, dummy pads 230, and chip pads 220 on the backside surface 204. The image sensor chip 200 may be attached onto the adhesive layer 150 such that the front surface 202 faces the upper surface 102 of the package substrate 100.

A plurality of lenses 212 may include a hemispherical microlens arranged in an array form (i.e., configuration or pattern). The hemispherical microlens may focus incident light on the image sensor chip 200. The dummy pads 230 may be arranged to surround the plurality of lenses 212. The chip pads 220 may be arranged to surround the dummy pads 230. For example, the dummy pads 230 and the chip pads 220 may be arranged to surround the plurality of lenses 212 in two rows. The chip pads 220 may be arranged in an outer portion of the pad region PR compared to the dummy pads 230. The rows may extend in at least one direction and may extend in a first direct and a second direction along the perimeter of the image sensor chip 200.

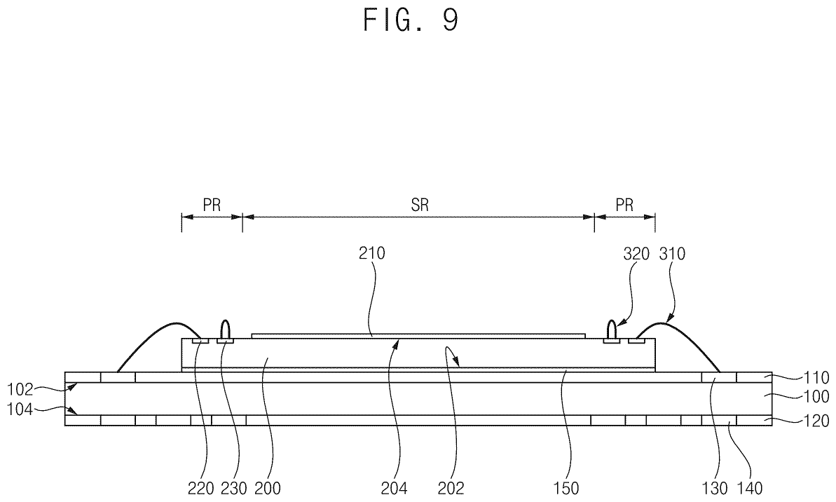

Referring to FIGS. 8 and 9, a bonding wire 310 may be formed to electrically connect the image sensor chip 200 to the package substrate 100, and a reinforcement wire structure 320 may be formed on the dummy pads 230.

In example embodiments, the bonding wire 310 may electrically connect the upper substrate pads 130 on the upper surface 102 of the package substrate 100 to the chip pads 220 on the image sensor chip 200. For example, a first end of the bonding wire 310 may be bonded on the upper substrate pads 130, and a second end opposite to the first end may be formed to be bonded to the chip pads 220. The bonding wire 310 may include a metal such as gold (Au), but example embodiments are not limited thereto.

The dummy pad 230 may be disposed side by side along a first direction D1 in which one side of the image sensor chip 200 extends, and may include first dummy pads 230a and second dummy pads 230b that are arranged adjacent to each other. The first dummy pad 230a and the second dummy pads 230b may be arranged alternately (i.e., in an alternating arrangement).

In example embodiments, a reinforcement wire 321 may be formed to extend on at least one dummy pad 230.

First, a capillary CP configured to provide a conductive member that is used as a material of the reinforcement wire 321 may be positioned on the first dummy pad 230a, and a conductive ball formed near a tip of the capillary CP may come into contact with the first dummy pad 230a and then deformed to bond a first end portion 322 onto the first dummy pad 230a. Then, as the capillary CP continuously supplies the conductive member while moving, the conductive member may extend from the first dummy pad 230a to the second dummy pad 230b and bond a second end portion 324 onto the second dummy pad 230b to form the reinforcement wire 321. That is, the reinforcement wire 321 may connect (e.g. electrically connect) the first dummy pad 230a to the second dummy pad 230b. In this case, the first dummy pad 230a and the second dummy pad 230b may be connected to a same ground. Accordingly, even when the first dummy pad 230a and the second dummy pad 230b are electrically connected by the reinforcement wire 321, an electrical short may be prevented. The reinforcement wires 321 may be arranged along the first dummy pads 230a and the second dummy pads 230b that are disposed alternately. Each of the reinforcement wires 321 may be formed to be electrically insulated from each other.

The reinforcement wire 321 may include copper (Cu), aluminum (Al), tungsten, nickel (Ni), molybdenum (Mo), gold (Au), silver (Ag), chromium (Cr), tin (Sn), or titanium (Ti), etc.

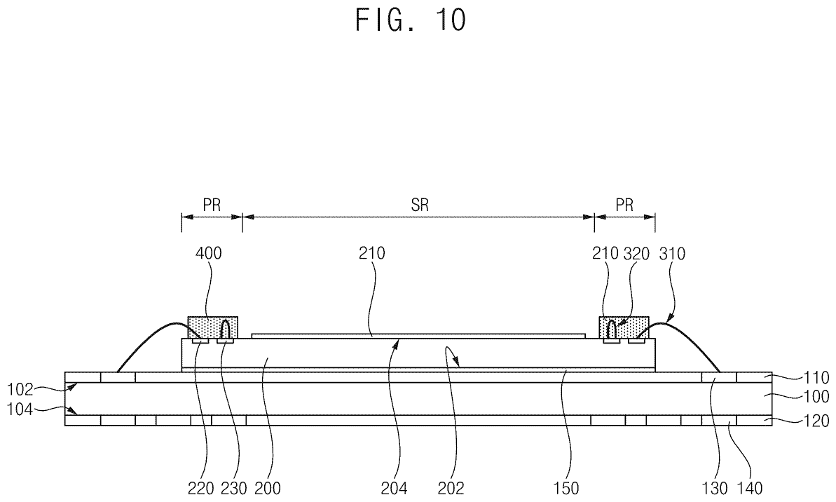

Referring to FIG. 10, a dam structure 400 may be formed on the image sensor chip 200.

In example embodiments, the dam structure 400 may be formed on the backside surface 204 of the image sensor chip 200. The image sensor chip 200 may have a sensing region SR and a pad region PR at least partially surrounding the sensing region SR. The dam structure 400 may be formed on the pad region PR of the image sensor chip 200. The dam structure 400 may be formed to extend in a direction perpendicular to (i.e., along the perimeter of) the backside surface 204 of the image sensor chip 200 in a rectangular ring shape or an annular shape along a circumference (i.e., perimeter) of the backside surface 204 of the image sensor chip 200. The dam structure 400 may be formed to cover or overlap the dummy pads 230 and the reinforcement wire structure 320 disposed on the dummy pads 230. Additionally, the dam structure 400 may be formed to cover or overlap the chip pads 220 and end portions of the bonding wire 310 connected to the chip pads 220. The dam structure 400 may be formed to have a flat upper surface and may support a glass as described below.

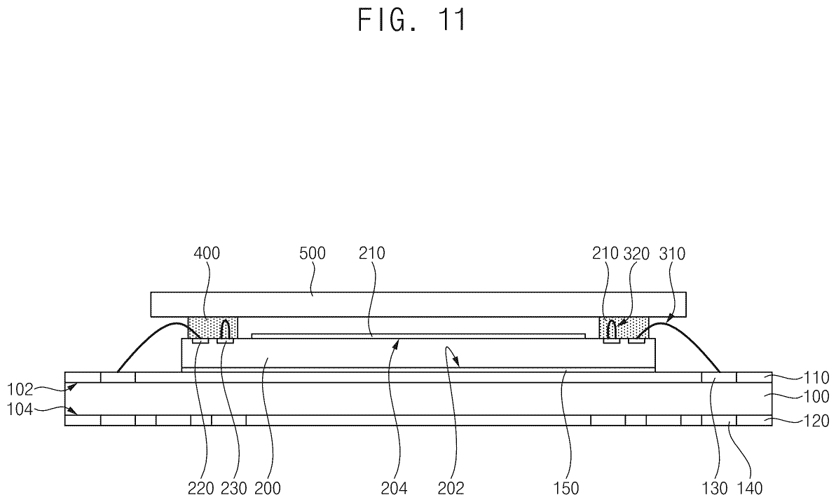

Referring to FIG. 11, a glass 500 may be formed on the dam structure 400.

In example embodiments, the glass 500 may be disposed on the backside surface 204 of the image sensor chip 200. Specifically, the glass 500 may be disposed on the dam structure 400 to be supported by the dam structure 400. The dam structure 400 may exist in a viscous state, and then may be hardened and solidified after the glass 500 is disposed. For example, the dam structure 400 may be thermally cured to be solidified. The glass 500 may be disposed to be spaced apart from the backside surface 204 of the image sensor chip 200 by a height of the dam structure 400. The glass 500 may allow an optical signal to reach the lens layer 210 on the image sensor chip 200. The glass 500 may include a material, such as a transparent glass or a transparent resin, but example embodiments are not limited thereto.

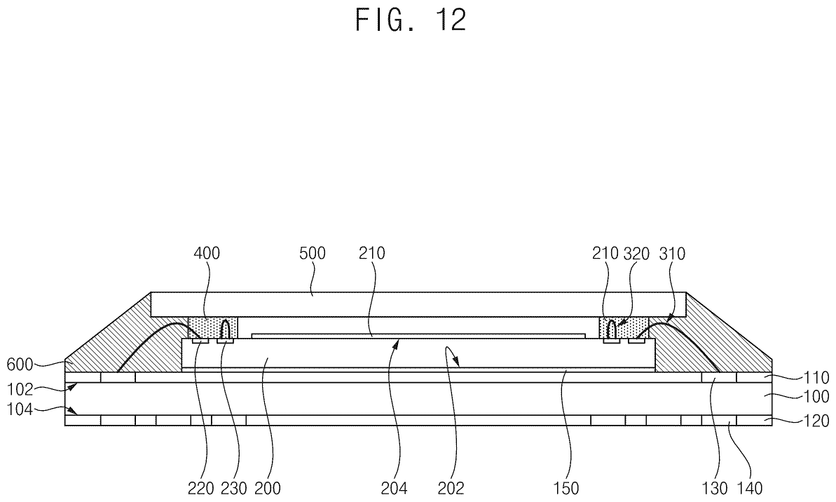

Referring to FIG. 12, a molding member 600 may be formed on the package substrate 100.

In example embodiments, the molding member 600 may be formed on the package substrate 100 to cover or overlap the image sensor chip 200 and the bonding wire 310. The molding member 600 may be formed to cover or overlap a side surface of the glass 500. The molding member 600 may be formed to be in contact with a portion of a lower surface 504 of the glass 500, an outer surface 406 of the dam structure 400, and a portion of the backside surface 204 of the image sensor chip 200. The molding member 600 may be formed to cover or overlap a portion of the bonding wire 310 not covered or overlapped by the dam structure 400. The molding member 600 may prevent the lens layer 210 of the image sensor chip 200 from being contaminated by external pollutants together with the dam structure 400. Additionally, the molding member 600 may be formed to at least partially surround the image sensor chip 200 to protect the semiconductor package 10 from external impact.

Then, an external connection member 12 may be formed on the lower surface 104 of the package substrate 100 to complete the semiconductor package of FIG. 1.

According to the method of manufacturing the semiconductor package, the dam structure 400 may be formed to cover or overlap the dummy pads 230 and the reinforcement wire structure 320 disposed on the dummy pads 230. Since the reinforcement wire structure 320 extends within the dam structure 400 to support the dam structure 400, it may be possible to prevent deformation of the dam structure 400 due to external impact or thermal stress during the manufacturing process of the semiconductor package 10.

A semiconductor package according to example embodiments will be described below.

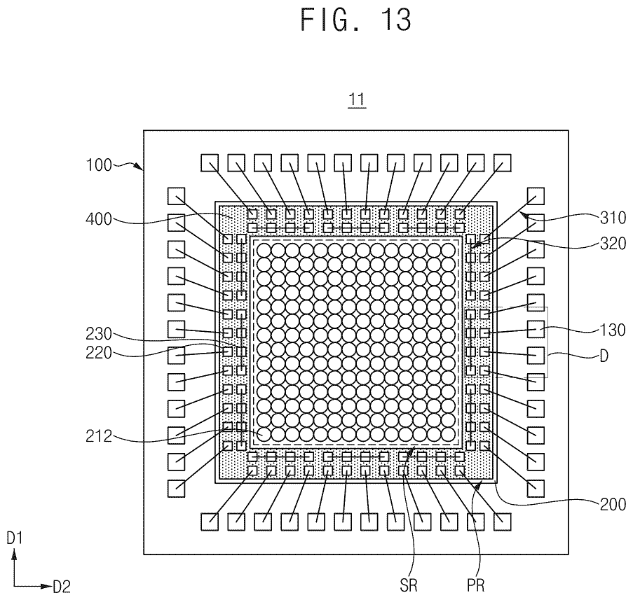

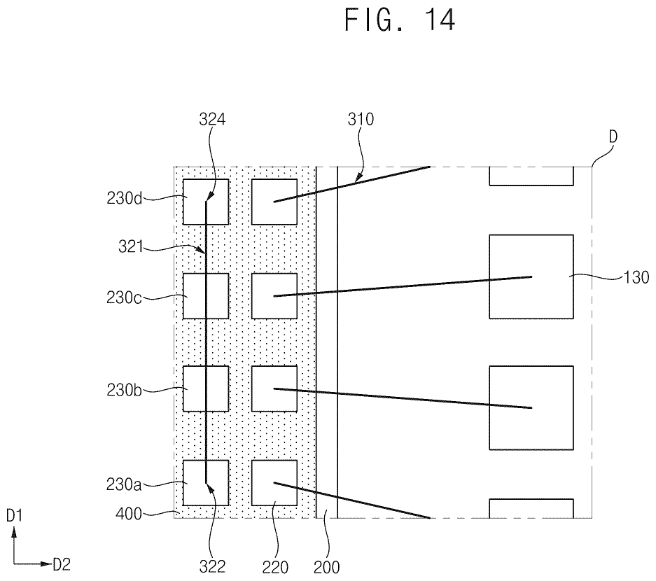

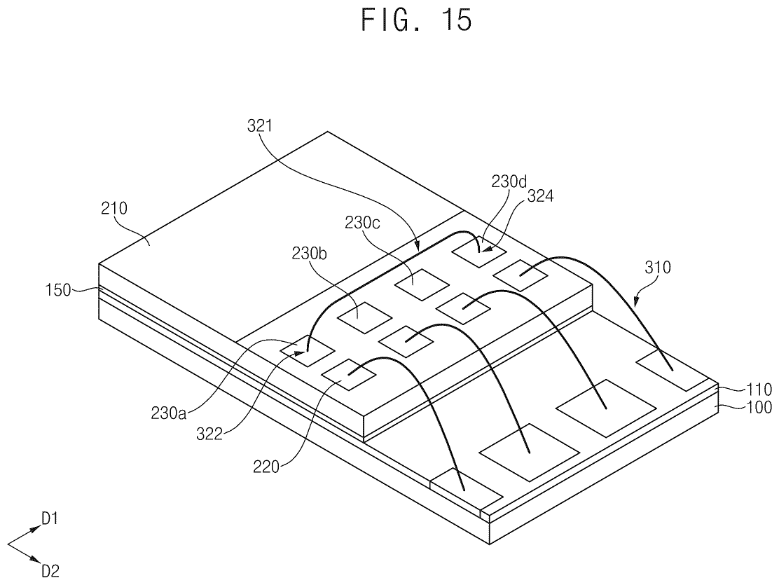

FIG. 13 is a plan view illustrating a semiconductor package in accordance with embodiments. FIG. 14 is an enlarged plan view of portion ‘D’ in FIG. 13. FIG. 15 is a perspective view illustrating portion ‘D’ in FIG. 13.

The semiconductor package according to an example embodiment may include substantially the same components as those of the semiconductor package shown in FIG. 1, except that a dummy pad includes first, second, third, and fourth dummy pads, a first end portion of a reinforcement wire is bonded on the first dummy pad, and a second end portion is bonded on the fourth dummy pad. Accordingly, the same components are denoted by the same reference numerals, and repeated descriptions of the same components may be omitted.

Referring to FIGS. 13, 14, and 15, a reinforcement wire structure 320 may be disposed on a dummy pad 230.

As illustrated in FIGS. 14 and 15, the dummy pad 230 may be disposed along a first direction D1 in which one side of the image sensor chip 200 extends, and may include first, second, third, and fourth dummy pads 230a, 230b, 230c, and 230d, respectively, arranged adjacent to each other. The first, second, third, and fourth dummy pads 230a, 230b, 230c, and 230d may include the first dummy pad 230a, the second dummy pad 230b adjacent to the first dummy pad 230a, the third dummy pad 230c adjacent to the second dummy pad 230b, and the fourth dummy pad 230d adjacent to the third dummy pad 230c in order along the first direction D1. The first, second, third, and fourth dummy pads 230a, 230b, 230c, and 230d may be in a repetitive sequence extending in at least one direction along the perimeter of the image sensor chip 200.

The reinforcement wire structure 320 may include a reinforcement wire 321 that extends from at least one dummy pad 230. The reinforcement wire 321 may have a first end portion 322 and a second end portion 324 opposite to the first end portion 322. For example, the first end portion 322 and the second end portion 324 of the reinforcement wire 321 may be bonded to different dummy pads 230, respectively.

The first end portion 322 may be bonded to the first dummy pad 230a, and the second end portion 324 may be bonded to the fourth dummy pad 230d. That is, the reinforcement wire 321 may electrically connect the first dummy pad 230a to the fourth dummy pad 230d. In this case, the first dummy pad 230a and the fourth dummy pad 230d may include pads connected to a same ground. Therefore, even when the first dummy pad 230a and the fourth dummy pad 230d are electrically connected by the reinforcement wire 321, an electrical short may be prevented.

The first dummy pad 230a and the second dummy pad 230b may be pads connected to different grounds. The first dummy pad 230a and the third dummy pad 230c may be pads connected to different grounds. The fourth dummy pad 230d and the second dummy pad 230b may be pads connected to different grounds. The fourth dummy pad 230d and the third dummy pad 230c may be pads connected to different grounds. The reinforcement wire 321 may be electrically insulated from the second dummy pad 230b and the third dummy pad 230c. Accordingly, even when the first dummy pad 230a and the fourth dummy pad 230d are electrically connected to each other, the reinforcement wire 321 may not be electrically connected to the second dummy pad 230b and the third dummy pad 230c, thereby preventing an electrical short.

The dam structure 400 may be disposed to cover or overlap the dummy pads 230 and the reinforcement wire structure 320 disposed on the dummy pads 230. Since the reinforcement wire structure 320 is disposed inside the dam structure 400 to support the dam structure 400, deformation due to external impact or thermal stress may be prevented from occurring in the dam structure 400.

A semiconductor package according to example embodiments will be described below.

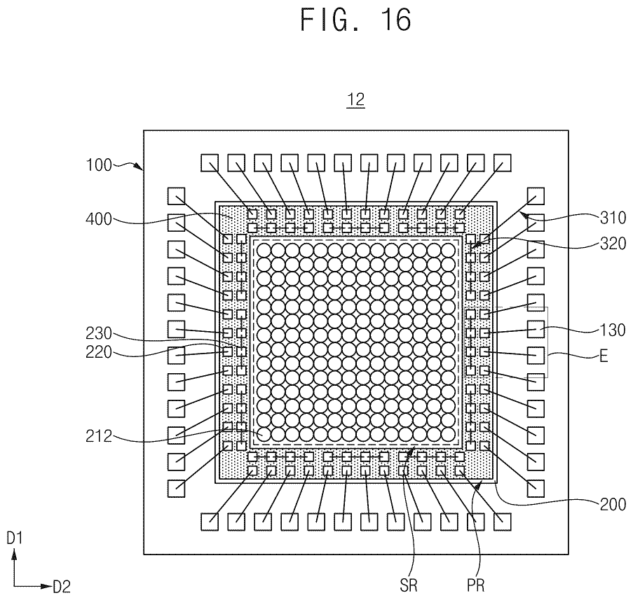

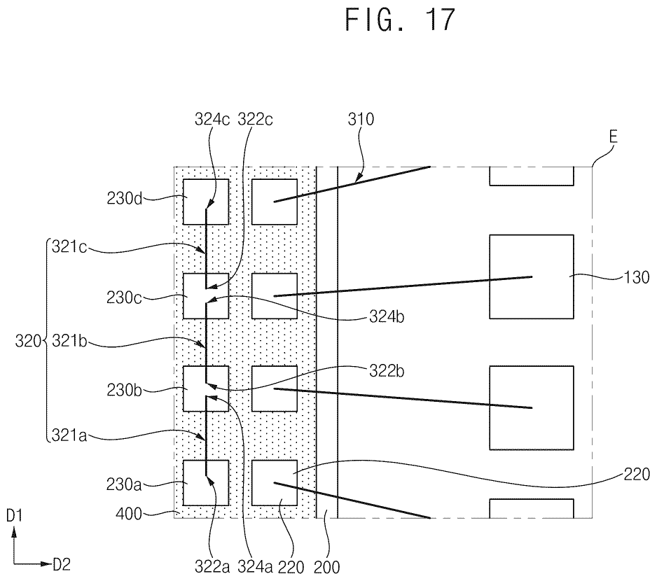

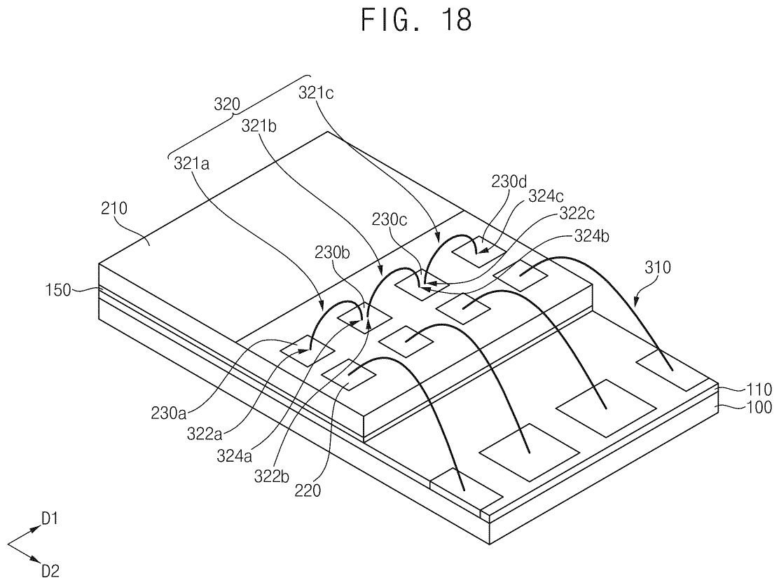

FIG. 16 is a plan view illustrating a semiconductor package in accordance with example embodiments. FIG. 17 is an enlarged plan view of portion ‘E’ in FIG. 16. FIG. 18 is a perspective view illustrating portion ‘E’ on FIG. 16.

The semiconductor package according to the present embodiment may include substantially the same components as those of the semiconductor package shown in FIG. 1, except that a dummy pad includes first, second, third, and fourth dummy pads and a reinforcement wire structure includes first, second, and third reinforcement wires. Accordingly, the same components are denoted by the same reference numerals, and repeated descriptions of the same components may be omitted.

Referring to FIGS. 16, 17, and 18, a reinforcement wire structure 320 may be disposed on a dummy pad 230. The reinforcement wire structure 320 may include a first reinforcement wire 321a, a second reinforcement wire 321b, and a third reinforcement wire 321c. The first reinforcement wire 321a, the second reinforcement wire 321b, and the third reinforcement wire 321c may be arranged in order along a first direction D1.

As illustrated in FIGS. 17 and 18, the dummy pad 230 may be disposed along the first direction D1 in which one side of the image sensor chip 200 extends, and may include first, second, third, and fourth dummy pads 230a, 230b, 230c, and 230d arranged adjacent to each other. The first, second, third, and fourth dummy pads 230a, 230b, 230c, and 230d may include the first dummy pad 230a, the second dummy pad 230b adjacent to the first dummy pad 230a, the third dummy pad 230c adjacent to the second dummy pad 230b, and the fourth dummy pad 230d adjacent to the third dummy pad 230c in order along the first direction D1.

The first reinforcement wire 321a may have a first end portion 322a and a second end portion 324a opposite to the first end portion 322a. The first end portion 322a may be bonded to the first dummy pad 230a, and the second end portion 324a may be bonded to the second dummy pad 230b. That is, the first reinforcement wire 321a may connect (e.g. electrically connect) the first dummy pad 230a to the second dummy pad 230b. In this case, the first dummy pad 230a and the second dummy pad 230b may include pads connected to a same ground. Therefore, even when the first dummy pad 230a and the second dummy pad 230b are electrically connected to each other by the first reinforcement wire 321a, an electrical short may be prevented.

The second reinforcement wire 321b may have a first end portion 322b and a second end portion 324b opposite the first end portion 322b. The first end portion 322b may be bonded to the second dummy pad 230b, and the second end portion 324b may be bonded to the third dummy pad 230c. That is, the second reinforcement wire 321b may connect (e.g. electrically connect) the second dummy pad 230b to the third dummy pad 230c. The second dummy pad 230b and the third dummy pad 230c may include pads connected to the same ground. Therefore, even when the second dummy pad 230b and the third dummy pad 230c are electrically connected by the second reinforcement wire 321b, an electrical short may be prevented.

The third reinforcement wire 321c may have a first end portion 322c and a second end portion 324c opposite the first end portion 322c. The first end portion 322c may be bonded to the third dummy pad 230c, and the second end portion 324c may be bonded to the fourth dummy pad 230d. That is, the third reinforcement wire 321c may connect (e.g. electrically connect) the third dummy pad 230c to the fourth dummy pad 230d. In this case, the third dummy pad 230c and the fourth dummy pad 230d may include pads connected to the same ground. Therefore, even when the third dummy pad 230c and the fourth dummy pad 230d are electrically connected to each other by the third reinforcement wire 321c, an electrical short may be prevented.

The second end portion 324a of the first reinforcement wire 321a and the first end portion 322b of the second reinforcement wire 321b may be bonded on the second dummy pad 230b respectively. The first reinforcement wire 321a and the second reinforcement wire 321b may be bonded on the second dummy pad 230b to be spaced apart from each other. In other words, the first reinforcement wire 321a may have a second end portion 324a electrically connected to the second dummy pad 230b and the second reinforcement wire 321b may have a first end portion 322b electrically connected to the second dummy pad 230b. The first reinforcement wire 321a may not be electrically connected to (i.e., may be electrically insulated from) the second reinforcement wire 321b. In some embodiments, the first reinforcement wire 321a and the second reinforcement wire 321b may be bonded to be in contact with each other.

The first end portion 322c of the third reinforcement wire 321c and the second end portion 324b of the second reinforcement wire 321b may be bonded on the third dummy pad 230c, respectively. The second reinforcement wire 321b and the third reinforcement wire 321c may be bonded on the second dummy pad 230b to be spaced apart from each other. In some embodiments, the second reinforcement wire 321b and the third reinforcement wire 321c may be bonded to be in contact with each other. In other words, the second reinforcement wire 321b and the third reinforcement wire 321c may be electrically connected or electrically insulated from each other.

The first dummy pad 230a, the second dummy pad 230b, the third dummy pad 230c, and the fourth dummy pad 230d may be electrically connected to each other by the first reinforcement wire 321a, the second reinforcement wire 321b, and the third reinforcement wire 321c. The first, second, third, and fourth dummy pads 230a, 230b, 230c, and 230d may be connected to a same ground.

The dam structure 400 may be disposed to cover or overlap the dummy pads 230 and the reinforcement wire structure 320 disposed on the dummy pads 230. Since the reinforcement wire structure 320 is disposed inside the dam structure 400 to support the dam structure 400, it may be possible to prevent deformation of the dam structure 400 due to external impact or thermal stress during the manufacturing process of the semiconductor package 10 or after the semiconductor package 10 is completed.

The foregoing is illustrative of example embodiments and is not to be construed as limiting thereof. Although a few example embodiments have been described, those skilled in the art will readily appreciate that many modifications are possible without departing from the novel teachings and advantages of the present invention. Accordingly, all such modifications are intended to be included within the scope of example embodiments as defined in the claims.

What is claimed is:

1. A semiconductor package, comprising:
a package substrate;
a plurality of upper substrate pads on an upper surface of the package substrate;
an image sensor chip on the package substrate,
wherein the image sensor chip includes a sensing region and a pad region at least partially surrounding the sensing region, a plurality of chip pads in the pad region and a plurality of dummy pads in the pad region;
a plurality of bonding wires each electrically connecting respective ones of the plurality of upper substrate pads of the package substrate to respective ones of the plurality of chip pads;
a reinforcement wire structure including a plurality of reinforcement wires each connecting to at least two dummy pads of the plurality of dummy pads;
a dam structure on the plurality of dummy pads and on the reinforcement wire structure that is on the pad region of the image sensor chip;
a glass on the dam structure and overlapping the image sensor chip; and
a molding member on the image sensor chip and on the plurality of bonding wires.

2. The semiconductor package of claim 1, wherein the image sensor chip further comprises a plurality of lenses on the sensing region.

3. The semiconductor package of claim 1, wherein the plurality of dummy pads at least partially surround the sensing region in plan view, and the plurality of chip pads are arranged in an outer portion of the pad region compared to the plurality of dummy pads in the plan view.

4. The semiconductor package of claim 1, wherein the plurality of dummy pads includes a plurality of first dummy pads and a plurality of second dummy pads that are spaced apart in an alternating arrangement extending along a portion of the pad region, and
wherein ones of the plurality of reinforcement wires include a first end portion connected to a respective first dummy pad of the plurality of first dummy pads and a second end portion opposite to the first end portion and connected to a respective second dummy pad of the plurality of second dummy pads.

5. The semiconductor package of claim 1, wherein the plurality of dummy pads includes a plurality of first dummy pads, a plurality of second dummy pads and a plurality of third dummy pads spaced apart in a repetitive sequence extending in at least one direction, and
wherein the plurality of reinforcement wires includes a plurality of first reinforcement wires that connects respective ones of the plurality of first dummy pads to respective ones of the plurality of second dummy pads and a plurality of second reinforcement wires that connects respective ones of the plurality of second dummy pads to respective ones of the plurality of third dummy pads.

6. The semiconductor package of claim 1, wherein the plurality of dummy pads includes a plurality of first dummy pads, a plurality of second dummy pads, a plurality of third dummy pads, and a plurality of fourth dummy pads spaced apart in a repetitive sequence extending in at least one direction, and
wherein the plurality of reinforcement wires connects respective ones of the plurality of first dummy pads to respective ones of the plurality of fourth dummy pads.

7. The semiconductor package of claim 1, wherein the dam structure is on the plurality of chip pads and on the plurality of bonding wires.

8. The semiconductor package of claim 1, wherein the dam structure comprises a rectangular annular shape.

9. The semiconductor package of claim 1, wherein the dam structure is offset from a perimeter of a backside surface of the image sensor chip.

10. The semiconductor package of claim 1, wherein the image sensor chip further includes a front surface facing the package substrate and a backside surface opposite to the front surface, and
wherein the plurality of chip pads and the plurality of dummy pads are on the backside surface of the image sensor chip.

11. A semiconductor package comprising:
a package substrate;
an image sensor chip on the package substrate including a sensing region, a pad region at least partially surrounding the sensing region, a plurality of lenses in the sensing region and a plurality of chip pads in the pad region;
a plurality of dummy pads including a plurality of first dummy pads and a plurality of second dummy pads in the pad region of the image sensor chip;
a reinforcement wire structure including a plurality of reinforcement wires each including a first end portion connected to a first dummy pad of the plurality of first dummy pads and a second end portion opposite to the first end portion that is connected to a second dummy pad of the plurality of second dummy pads;
a plurality of bonding wires each electrically connecting respective ones of a plurality of upper substrate pads to respective ones of the plurality of chip pads;
a dam structure on the plurality of dummy pads and on the reinforcement wire structure that is on the pad region of the image sensor chip;
a glass on the dam structure and overlapping the image sensor chip; and
a molding member on the image sensor chip and on the plurality of bonding wires.

12. The semiconductor package of claim 11, wherein the plurality of dummy pads at least partially surround the sensing region in plan view, and
wherein the plurality of chip pads are arranged in an outer portion of the pad region compared to the plurality of dummy pads in the plan view.

13. The semiconductor package of claim 11, wherein the plurality of first dummy pads and the plurality of second dummy pads are spaced apart in an alternating arrangement.

14. The semiconductor package of claim 11, wherein the plurality of dummy pads further includes a plurality of third dummy pads, and the plurality of first dummy pads, the plurality of second dummy pads and the plurality of third dummy pads are spaced apart in a repetitive sequence in at least one direction,
wherein the plurality of reinforcement wires includes a plurality of first reinforcement wires and a plurality of second reinforcement wires,
wherein the plurality of first reinforcement wires connects respective ones of the plurality of first dummy pads to respective ones of the plurality of second dummy pads, and
wherein the plurality of second reinforcement wires connects respective ones of the plurality of second dummy pads to respective ones of the plurality of third dummy pads.

15. The semiconductor package of claim 11, wherein the plurality of dummy pads further includes a plurality of third dummy pads adjacent to respective ones of the plurality of second dummy pads.

16. The semiconductor package of claim 11, wherein the dam structure is on the plurality of chip pads and on the plurality of bonding wires.

17. The semiconductor package of claim 11, wherein the dam structure comprises a rectangular annular shape.

18. The semiconductor package of claim 11, wherein the molding member is in contact with a lower surface of the glass, an outer surface of the dam structure and a backside surface of the image sensor chip.

19. The semiconductor package of claim 11, wherein the package substrate includes the plurality of upper substrate pads on an upper surface of the package substrate and a plurality of lower substrate pads on a lower surface opposite to the upper surface,
wherein the semiconductor package, further comprises a plurality of external connection members on the plurality of lower substrate pads, respectively.

20. A semiconductor package, comprising:
a package substrate including a plurality of upper substrate pads on an upper surface of the package substrate and a plurality of lower substrate pads on a lower surface opposite to the upper surface;
an image sensor chip on the upper surface of the package substrate, the image sensor chip including a sensing region, a pad region at least partially surrounding the sensing region, a plurality of lenses in the sensing region and a plurality of chip pads in the pad region;
a plurality of dummy pads including a plurality of first dummy pads and a plurality of second dummy pads in the pad region of the image sensor chip;
a plurality of bonding wires electrically connecting respective ones of the plurality of upper substrate pads of the package substrate to respective ones of the plurality of chip pads;
a reinforcement wire structure including a plurality of reinforcement wires wherein ones of the plurality of reinforcement wires include a first end portion connected to a respective first dummy pad of the plurality of first dummy pads and a second end portion opposite to the first end portion and connected to a respective second dummy pad of the plurality of second dummy pads;
a dam structure on the plurality of chip pads and on the plurality of dummy pads and on the plurality of bonding wires and on the reinforcement wire structure that is on the pad region of the image sensor chip;
a glass on the dam structure and on the image sensor chip;
a molding member on the image sensor chip and on the plurality of bonding wires; and
a plurality of external connection members on the plurality of lower substrate pads, respectively.
